(19) United States
(12) Patent Application Publication
(10) Pub. No.: US 2026/0254463 A1
(43) Pub. Date: Aug. 27, 2026

(54) SIGNAL PROCESSING DEVICE, SIGNAL PROCESSING METHOD, AND NON-TRANSITORY COMPUTER-READABLE MEDIUM

(71) Applicant: NEC Corporation, Tokyo (JP)

(72) Inventor: Takahiro ODAGAWA, Tokyo (JP)

(73) Assignee: NEC Corporation, Tokyo (JP)

(21) Appl. No.: 19/541,607

(22) Filed: Feb. 17, 2026

(30) Foreign Application Priority Data
Feb. 26, 2025 (JP) 2025-029189

(51) Int. Cl. H03M 7/50; H03M 7/30; H03M 7/40; H03M 7/46

(52) U.S. Cl. CPC H03M 7/50; H03M 7/30; H03M 7/3062; H03M 7/40; H03M 7/46

(57) ABSTRACT

A signal processing device according to the present disclosure includes a compression unit for generating a first compressed signal by compressing an input signal having a predetermined length extracted from a received signal in a time domain, a calculation unit for calculating cross-correlation between the first compressed signal and a second compressed signal generated by compressing a reference signal in a time domain, a specification unit for specifying a synchronous position in the first compressed signal based on a calculation result of the cross-correlation, and a conversion unit for converting the synchronous position in the first compressed signal into a synchronous position in the input signal.

### INCORPORATION BY REFERENCE

This application is based upon and claims the benefit of priority from Japanese patent application No. 2025-029189, filed on Feb. 26, 2025, the disclosure of which is incorporated herein in its entirety by reference.

### TECHNICAL FIELD

The present disclosure relates to a signal processing device, a signal processing method, and a program.

### BACKGROUND ART

In a transmission system such as optical communication, a reception device detects a signal sequence corresponding to a known preamble from received signals. Furthermore, the reception device executes signal processing such as demodulation or the like of a signal after performing frame synchronization of the received signals using the preamble.

JP 2010-531572 A discloses a configuration of a receiver including a cross correlator that estimates an absolute value of a cross-correlation measurement value based on input samples that are frequency coarsely-adjusted and quantized of a received signal.

### SUMMARY

In the receiver disclosed in JP 2010-531572 A, the amount of calculation related to cross-correlation increases as the length of an input signal used for executing cross-correlation increases. As a result, there is a problem that as the length of the input signal becomes longer, the arithmetic load in frame synchronization processing of the receiver increases.

An example object of the present disclosure is to provide a signal processing device, a signal processing method, and a program capable of suppressing an increase in an arithmetic load in the frame synchronization processing.

A signal processing device according to an example aspect of the present disclosure includes a compression unit for generating a first compressed signal by compressing an input signal having a predetermined length extracted from a received signal in a time domain, a calculation unit for calculating cross-correlation between the first compressed signal and a second compressed signal generated by compressing a reference signal in a time domain, a specification unit for specifying a synchronous position in the first compressed signal based on a calculation result of the cross-correlation, and a conversion unit for converting the synchronous position in the first compressed signal into a synchronous position in the input signal.

A signal processing method according to an example aspect of the present disclosure includes generating a first compressed signal by compressing an input signal having a predetermined length extracted from a received signal in a time domain, calculating cross-correlation between the first compressed signal and a second compressed signal generated by compressing a reference signal in a time domain, specifying a synchronous position in the first compressed signal based on a calculation result of the cross-correlation, and converting the synchronous position in the first compressed signal into a synchronous position in the input signal.

A program according to an example aspect of the present disclosure causes a computer to execute generating a first compressed signal by compressing an input signal having a predetermined length extracted from a received signal in a time domain, calculating cross-correlation between the first compressed signal and a second compressed signal generated by compressing a reference signal in a time domain, specifying a synchronous position in the first compressed signal based on a calculation result of the cross-correlation, and converting the synchronous position in the first compressed signal into a synchronous position in the input signal.

According to the present disclosure, a signal processing device, a signal processing method, and a program capable of suppressing an increase in arithmetic load in frame synchronization processing can be provided.

### BRIEF DESCRIPTION OF THE DRAWINGS

FIG. 1 illustrates a configuration example of a signal processing device;

FIG. 2 illustrates a flow of processing of a signal processing method executed in the signal processing device;

FIG. 3 illustrates a configuration example of the signal processing device;

FIG. 4 illustrates compressing an input signal;

FIG. 5 illustrates a flow of compression processing related to the input signal;

FIG. 6 illustrates a flow of compression processing related to a reference signal;

FIG. 7 illustrates a flow of synchronous position specifying processing; and

FIG. 8 is a block diagram illustrating configuration examples of a signal processing device and a signal processing device.

### EXAMPLE EMBODIMENT

### First Example Embodiment

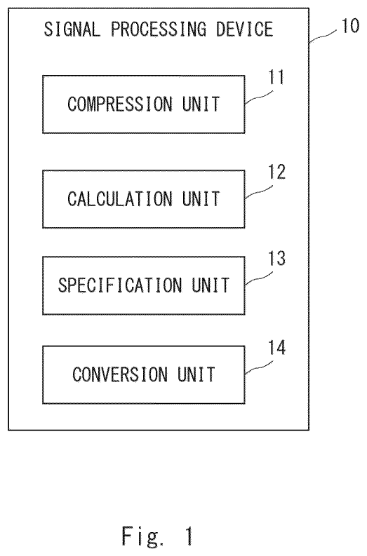

A configuration example of a signal processing device 10 will be described with reference to FIG. 1. The signal processing device 10 may be a computer device that operates by a processor executing a program stored in a memory. The signal processing device 10 may be a server device, an information processing device, or the like.

The signal processing device 10 includes a compression unit 11, a calculation unit 12, a specification unit 13, and a conversion unit 14. The compression unit 11, the calculation unit 12, the specification unit 13, and the conversion unit 14 may be software or a module in which processing is executed by a processor executing a program stored in a memory. Alternatively, the compression unit 11, the calculation unit 12, the specification unit 13, and the conversion unit 14 may be hardware such as a circuit or a chip.

FIG. 1 illustrates a configuration in which the signal processing device 10 includes the compression unit 11, the calculation unit 12, the specification unit 13, and the conversion unit 14, but the compression unit 11, the calculation unit 12, the specification unit 13, and the conversion unit 14 may be arranged in a distributed manner in two or more devices. A plurality of devices in which the compression unit 11, the calculation unit 12, the specification unit 13, and the conversion unit 14 are arranged in a distributed manner may, for example, perform communication via a network. A plurality of devices in which the compression unit 11, the calculation unit 12, the specification unit 13, and the conversion unit 14 are arranged in a distributed manner may constitute, for example, a signal processing system.

The compression unit 11 compresses an input signal having a predetermined length extracted from a received signal in a time domain to generate a first compressed signal. The received signal may be, for example, a signal received by the signal processing device 10 via a wireless communication line or a wired communication line. The wireless communication line may be, for example, a mobile communication line that supports a wireless Local Area Network (LAN), so-called fourth generation (4G) or fifth generation (5G) communication system. The wired communication line may be, for example, an optical communication line.

The input signal having the predetermined length extracted from the received signal may be a signal included in the received signal. The predetermined length may be, for example, the same length as the reference signal used for the synchronization processing. The predetermined length may indicate a temporal width. The predetermined length may be defined in, for example, units of symbols or units of frames. Specifically, the predetermined length may be defined as a length of one frame, a length of two frames, or the like. The frame may be data having a configuration including a frame header and a payload.

Compressing the input signal in the time domain may mean making the input signal having a predetermined length into a signal having a shorter length. That is, compressing the input signal in the time domain may be to make an input signal having a predetermined number of samples into a signal having a shorter number of samples. That is, compressing the input signal in the time domain may mean shortening the length of the input signal. In a case of compressing the input signal, a predefined standard or method may be used.

The calculation unit 12 calculates cross-correlation between the first compressed signal and a second compressed signal generated by compressing the reference signal in the time domain. The second compressed signal is generated using a standard or method similar to the standard or method with which the first compressed signal was used for generation. A predefined signal sequence may be used as the reference signal. The reference signal may be referred to as a known signal. It is assumed that the received signal includes a signal similar to the reference signal. The reference signal and the second compressed signal may be generated in the signal processing device 10, or may be generated in a device different from the signal processing device 10.

Calculating the cross-correlation between the first compressed signal and the second compressed signal may be calculating a value indicating the extent of similarity between the first compressed signal and the second compressed signal. The cross-correlation may be indicated using a product of the first compressed signal and the second compressed signal that is digital data.

The specification unit 13 specifies the synchronous position in the first compressed signal based on the calculation result of the cross-correlation. For example, in a case where the cross-correlation between the first compressed signal and the second compressed signal is calculated while shifting the position of the first compressed signal, if a value indicated as a calculation result is larger than a predetermined standard, the specification unit 13 may refer to the first compressed signal and the second compressed signal having correlation. The position of the first compressed signal may be a position indicating the head of the data, or may be a reference position in the data. The synchronous position may also be a position indicating the head of the data or a reference position in the data.

The conversion unit 14 converts the synchronous position in the first compressed signal into the synchronous position in the input signal. The first compressed signal is compressed using a predefined standard or method. Therefore, for example, the conversion unit 14 may perform an arithmetic operation of returning the arithmetic operation performed to generate the first compressed signal to the original state. For example, in a case where the first compressed signal is compressed in such a way that the length of the input signal becomes 1/n (n is a positive integer), the conversion unit 14 also multiplies the synchronous position by n similarly to the first compressed signal. As a result, the synchronous position in the input signal is specified.

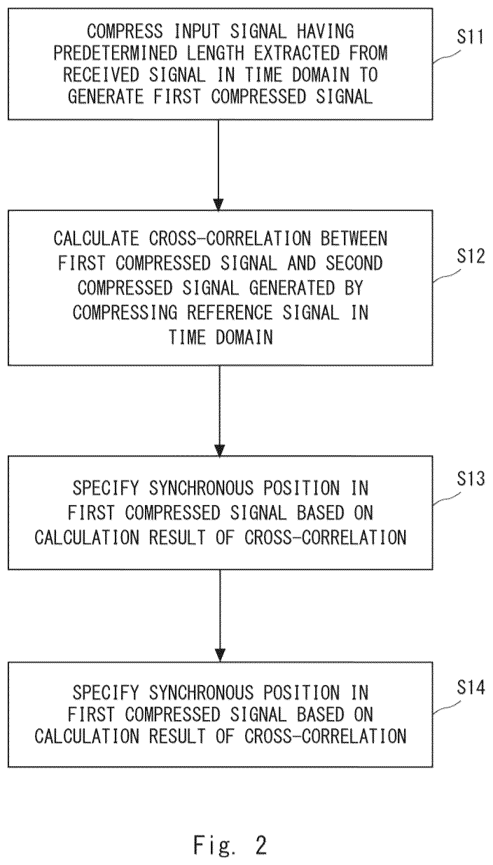

FIG. 2 illustrates a flow of processing of a signal processing method executed in the signal processing device 10. First, the compression unit 11 compresses an input signal having a predetermined length extracted from the received signal in the time domain to generate a first compressed signal (S11). Next, the calculation unit 12 calculates cross-correlation between the first compressed signal and a second compressed signal generated by compressing a reference signal in the time domain (S12). Then, the specification unit 13 specifies the synchronous position in the first compressed signal based on the calculation result of the cross-correlation (S13). Next, the conversion unit 14 converts the synchronous position in the first compressed signal to the synchronous position in the input signal (S14).

As described above, the signal processing device 10 calculates cross-correlation by using the first compressed signal in which the input signal is compressed in the time domain and the second compressed signal in which the reference signal is compressed in the time domain. That is, the signal processing device 10 can suppress the arithmetic load related to the cross-correlation by compressing the signal to be used for the cross-correlation.

### Second Example Embodiment

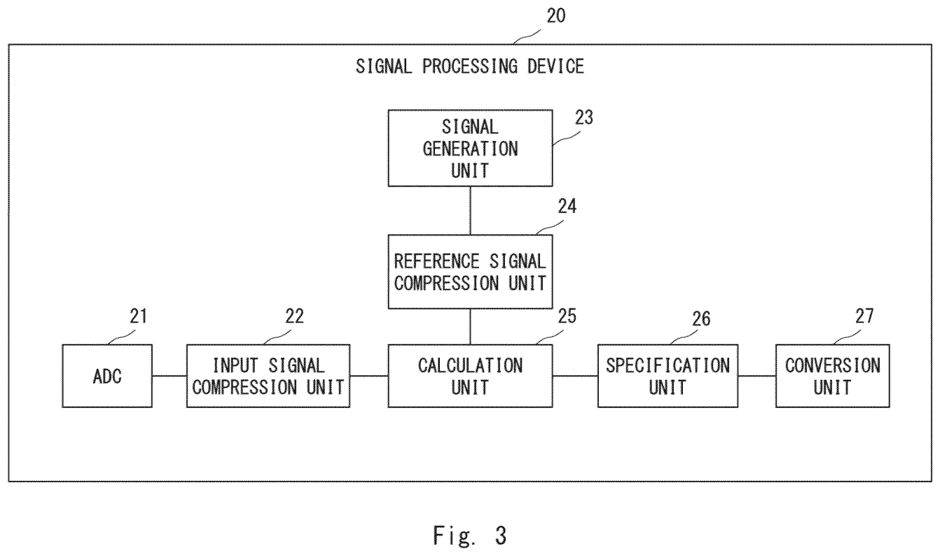

FIG. 3 illustrates a configuration example of the signal processing device 20. The signal processing device 20 corresponds to the signal processing device 10 in FIG. 1.

The signal processing device 20 includes an Analog to Digital Converter (ADC) 21, an input signal compression unit 22, a signal generation unit 23, a reference signal compression unit 24, a calculation unit 25, a specification unit 26, and a conversion unit 27. Each element including the signal processing device 20 may be included in one device as illustrated in FIG. 1, or may be arranged in two or more devices in a distributed manner.

The ADC 21 converts an analog electrical signal into a digital electrical signal. In a preceding stage of the ADC 21, an optical signal transmitted from another device may be converted into an analog electrical signal in a coherent receiver. The optical signal and the analog electrical signal correspond to received signals. The received signal may be a signal transmitted from another device.

The ADC 21 samples the analog electrical signal at a predetermined period. The predetermined period may be, for example, a period of one symbol, a period shorter than one symbol, or a period longer than one symbol. The digital electrical signal generated by the ADC 21 sampling every one symbol may be referred to as a 1 sample per symbol (sps) digital electrical signal. Furthermore, the digital electrical signal generated by the ADC 21 sampling in a period shorter than or a period longer than 1 symbol may be referred to as a fractional (non-integer oversampled) digital electrical signal. The fractional digital electrical signal may be referred to as an r sps digital electrical signal. r may be, for example, a value larger than 1 and smaller than 2.

The input signal compression unit 22 extracts an input signal of a predetermined period from the digital electrical signal. The input signal compression unit 22 extracts an input signal to be used for frame synchronization. For example, the input signal compression unit 22 may extract a signal having a length for one frame period as an input signal, or may extract a signal having a length for two frame periods as an input signal. The calculation load relating to the cross-correlation becomes lighter the shorter the length of the signal extracted as the input signal, but the synchronization probability becomes lower. In addition, the calculation load relating to the cross-correlation becomes heavier the longer the length of the signal extracted as the input signal, but the synchronization probability becomes higher. By extracting a length for two frame periods as the input signal, a preamble having a high correlation with the reference signal can be included in the input signal. Therefore, it is possible to improve the specifying probability of the synchronous position by using the input signal of two frame periods for the cross-correlation calculation.

Alternatively, the input signal compression unit 22 may extract an input signal of a predetermined period from the digital electrical signal on which processing such as wavelength dispersion compensation, Direct Current (DC) offset compensation, and normalization have been executed.

The input signal compression unit 22 compresses the input signal according to a predefined standard. Here, the compression processing executed in the input signal compression unit 22 will be described.

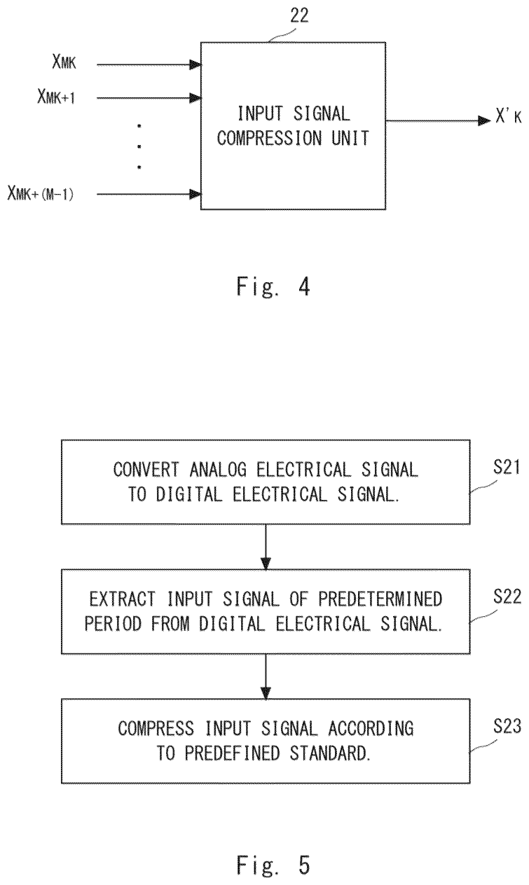

FIG. 4 illustrates compressing an input signal to a size of 1/M (“/” indicates division) (M indicates a value of one or greater). X_{MK}, X_{MK+1}, and X_{MK+(M-1)} indicate values of one sample of the digital electrical signal. The value of one sample of the digital electrical signal may be a value defined according to the amplitude of the analog electrical signal. That is, the value of one sample of the digital electrical signal may be larger the larger the amplitude of the analog electrical signal. X′_{K} represents an input signal after compression (hereinafter referred to as a compressed signal).

For example, a case where M=2 will be described. In a case where M=2, the input signal compression unit 22 generates X′_{K} based on X_{2K} and X_{2K+1}. K may be a value for identifying a sample of the compressed signal. That is, the input signal compression unit 22 generates a digital electrical signal for one sample from the digital electrical signal for two samples.

Specifically, in a case where M=2, the input signal compression unit 22 may generate X′_{K} by performing statistical processing on X_{2K} and X_{2K+1}. For example, the input signal compression unit 22 may generate X′_{K} by setting X′_{K}=X_{2K}+X_{2K+1}. Alternatively, the input signal compression unit 22 may set the average of X_{2K} and X_{2K+1} to X′_{K}. Alternatively, the input signal compression unit 22 may set a digital signal having a larger value out of X_{2K} and X_{2K+1} as X′_{K}, or may set a digital signal having a smaller value as X′_{K}. Alternatively, the input signal compression unit 22 may perform weighting on either one or both of X_{2K} and X_{2K+1}, and perform statistical processing using the value on which weighting has been performed.

For example, the input signal compression unit 22 may generate X′_{K} according to the following formula.

$${X}_{K}^{′} = {\sum }_{i = M K}^{M ( K + 1 ) - 1} {X}_{i}$$

Returning to FIG. 3, the signal generation unit 23 generates a reference signal. The reference signal is a known signal used to perform frame synchronization. That is, a predefined signal sequence is used as the reference signal. The reference signal may be, for example, a signal having the same length as the input signal. Specifically, the reference signal may be a signal including a signal sequence set in the preamble of the received signal. Furthermore, in the reference signal, any value may be set in a data area other than the signal sequence set in the preamble. For example, any value may all be set to 0, or other values may be set. Alternatively, the signal sequence set in the preamble may be repeatedly set in the reference signal. Here, the same signal as the signal sequence set in the preamble may be set at the head of the reference signal, or may be set at a predefined location in the reference signal.

The reference signal compression unit 24 compresses the reference signal according to a predefined standard. The reference signal compression unit 24 compresses the reference signal according to the standard same as the standard used in a case where the input signal is compressed in the input signal compression unit 22. The length of the reference signal after compression may be the same as the length of the input signal after compression.

The calculation unit 25 calculates cross-correlation between the compressed input signal (hereinafter referred to as a first compressed signal) and the compressed reference signal (hereinafter referred to as a second compressed signal). The cross-correlation may be obtained by multiplying the sample included in the first compressed signal and the sample included in the second compressed signal in order from the head of each signal and adding the products. A method of calculating the cross-correlation is not limited to a specific method, and various known methods may be used. The calculation result of the cross-correlation may be referred to as, for example, a correlation coefficient. The calculation unit 25 may calculate the correlation coefficient at each position of the first compressed signal while temporally shifting the head position of the first compressed signal to be multiplied by the second compressed signal. The temporally shifting may be, for example, shifting by one sample.

The correlation coefficient may be calculated as a value between −1 and 1. In a case where the correlation coefficient is 0, this means that the correlation between the first compressed signal and the second compressed signal is the lowest or the weakest, and as the correlation coefficient approaches 1, this means that the positive correlation between the first compressed signal and the second compressed signal becomes higher or stronger. In addition, as the correlation coefficient approaches −1, this means that the negative correlation between the first compressed signal and the second compressed signal becomes higher or stronger.

The signal processing device 20 specifies the head position of the frame by detecting the preamble included in the input signal. The value indicating the correlation between the reference signal and the preamble becomes higher by using the signal sequence substantially the same as the reference signal for the preamble. As a result, the signal processing device 20 can synchronize the frames, and can specify the position of the frame, for example, the head position of the frame. If the value indicating the correlation becomes high, this may mean that the value indicating the correlation between the reference signal and the preamble at a specific position becomes higher than the value indicating the correlation between the reference signal and the preamble at another position. The value indicating the correlation between the reference signal and the preamble at a specific position is significantly higher than the value indicating the correlation between the reference signal and the preamble at another position, and may form a so-called peak.

The specification unit 26 specifies a synchronous position of the first compressed signal and the second compressed signal according to the correlation coefficient. For example, the specification unit 26 may specify, as the synchronous position, the head position of the first compressed signal in a case where the value or the absolute value of the correlation coefficient is closest to 1.

The conversion unit 27 converts the synchronous position of the first compressed signal into a position in the input signal. For example, in a case where the input signal is compressed to 1/M by the input signal compression unit 22, the conversion unit 27 may set the synchronous position of the first compressed signal to M times. Furthermore, in a case where the input signal is a fractional digital electrical signal of r sps, the conversion unit 27 may multiply the synchronous position of the first compressed signal by M/r. In a case where the value multiplied by M/r becomes a fractional number, the position in the input signal may be set to an integer closest to the fractional number or an integer obtained by rounding up or rounding down after the decimal point.

FIG. 5 illustrates a flow of compression processing related to the input signal. First, the ADC 21 converts the analog electrical signal into a digital electrical signal (S21). For example, the ADC 21 samples the analog electrical signal at a predetermined period. The ADC 21 may convert the analog electrical signal into a 1 sps digital electrical signal or an r sps digital electrical signal according to the sampling period.

Next, the input signal compression unit 22 extracts an input signal of a predetermined period from the digital electrical signal (S22). For example, the input signal compression unit 22 may extract a signal having a length for two frame periods as the input signal.

Next, the input signal compression unit 22 compresses the input signal according to a predefined standard (S23). For example, the input signal compression unit 22 may compress the input signal to 1/M according to a predefined standard.

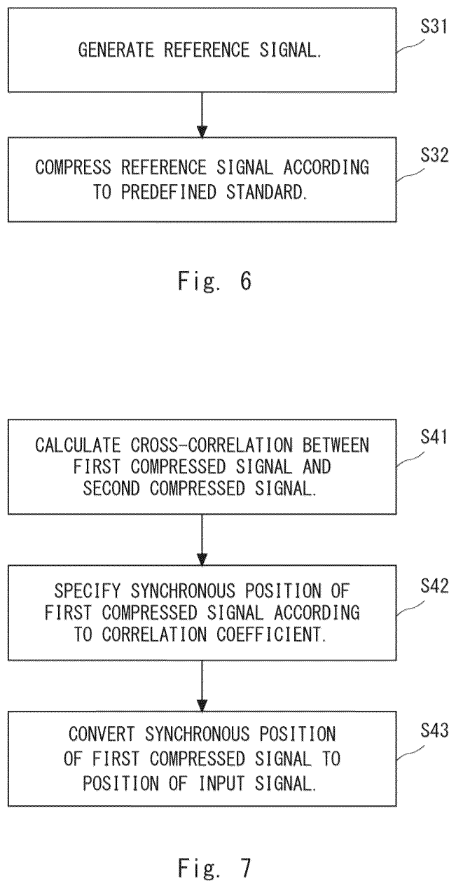

FIG. 6 illustrates a flow of compression processing related to a reference signal. First, the signal generation unit 23 generates a reference signal (S31). For example, in a case where the input signal is a fractional digital electrical signal of r sps by the ADC, the signal generation unit 23 may generate the reference signal by converting a known signal that is a symbol string of 1 sps into a signal of r sps by interpolation complement. Next, the reference signal compression unit 24 compresses the reference signal according to a predefined standard (S32). The reference signal compression unit 24 compresses the reference signal according to a standard similar to the standard used by the input signal compression unit 22.

FIG. 7 illustrates a flow of synchronous position specifying processing. First, the calculation unit 25 calculates cross-correlation between the first compressed signal and the second compressed signal (S41). The first compressed signal is a compressed input signal and the second compressed signal is a compressed reference signal. As a result of calculating the cross-correlation, the calculation unit 25 calculates a correlation coefficient regarding each of the first compressed signals having different head positions in a case where the cross-correlation with the second compressed signal is performed.

Next, the specification unit 26 specifies the synchronous position of the first compressed signal according to the correlation coefficient (S42). For example, the specification unit 26 may specify, as the synchronous position, the head position of the first compressed signal having the largest correlation coefficient. Next, the conversion unit 27 converts the synchronous position of the first compressed signal into the position of the input signal (S43). Specifically, in a case where the input signal is compressed to 1/M, the conversion unit 27 multiplies the synchronous position of the first compressed signal by M to convert into the position of the input signal.

As described above, the signal processing device 20 executes the synchronous position specifying processing using the compressed input signal and the compressed reference signal. As a result, the length of the signal used for the specifying processing of the synchronous position can be made shorter than that before compression. As a result, the processing load of the processing of specifying the synchronous position using the compressed signal can be reduced as compared with the case where the specifying processing of the synchronous position is executed using the signal that is not compressed.

Furthermore, in the second example embodiment, the example of calculating the cross-correlation in the time domain has been mainly described, but the cross-correlation may be calculated in the frequency domain.

For example, the calculation unit 25 may calculate cross-correlation using information in the frequency domain after performing fast Fourier transform (FFT) on the compressed input signal and information in the frequency domain after performing FFT on the compressed reference signal. Here, in order to make the length of the compressed input signal to the natural power of 2, a sample indicating zero may be added to the compressed input signal. In addition, in order to make the length of the compressed reference signal to the natural power of 2, a sample indicating zero may be added to the compressed reference signal.

The calculation unit 25 can output the cross-correlation coefficient in the time domain to the specification unit 26 by executing inverse FFT (IFFT) on the result of the cross-correlation. As described above, in the calculation of the cross-correlation in the frequency domain as well, the processing load of the synchronous position specifying processing can be reduced by using the compressed signal.

### Third Example Embodiment

Next, an example of compression processing of an input signal and a reference signal different from that of the second example embodiment will be described. Here, a case where the input signal is a 1 sps digital electrical signal and there is a temporal spread such as spatial mode dispersion will be described. The spatial mode dispersion is, for example, an event that occurs in a long-distance transmission system using a coupled multicore fiber and causes a difference in light arrival time. The temporal spread due to spatial mode dispersion means that a pulse of light spreads on a time axis due to occurrence of spatial mode dispersion. In a case where there is no temporal spread due to the spatial mode dispersion, the influence caused by the spread of the pulse of light on the time axis is small. Therefore, each sample included in the input signal is less affected by an adjacent sample. On the other hand, in a case where there is a temporal spread due to the spatial mode dispersion, the pulse of light spreads on the time axis, so that each sample included in the input signal is greatly affected by an adjacent sample.

In a case where there is temporal spread due to the spatial mode dispersion, the input signal compression unit 22 and the reference signal compression unit 24 may compress the input signal and the reference signal by periodically extracting samples from the input signal and the reference signal that are 1 sps digital electrical signals. The input signal compression unit 22 and the reference signal compression unit 24 compress the signal to 1/M by extracting samples every M (M is an integer equal to or greater than two) periods from the input signal and the reference signal.

As described above, in a case where the input signal is a 1 sps digital electrical signal and there is a temporal spread such as spatial mode dispersion, the signal is compressed by periodically extracting samples. The periodic extraction of the samples can reduce the load of the compression processing as compared with the case of compressing the signal by adding a plurality of samples.

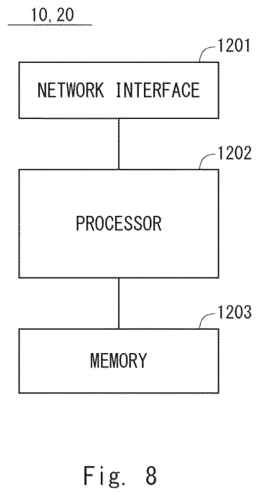

FIG. 8 is a block diagram illustrating a configuration example of the signal processing device 10 and the signal processing device 20 (hereinafter referred to as the signal processing device 10 and the like). Referring to FIG. 8, the signal processing device 10 and the like include a network interface 1201, a processor 1202, and a memory 1203. The network interface 1201 may be used to communicate with network nodes. The network interface 1201 may include, for example, a Network Interface Card (NIC) conforming to IEEE 802.3 series. IEEE represents Institute of Electrical and Electronics Engineers.

The processor 1202 executes processing of the signal processing device 10 and the like described with reference to the flowchart, by reading and executing a software component (computer program) from the memory 1203. The processor 1202 may be, for example, a Micro Processor Unit (MPU) or a Central Processing Unit (CPU). The processor 1202 may include a plurality of processors.

The memory 1203 is constituted by a combination of a volatile memory and a nonvolatile memory. The memory 1203 may include a storage arranged away from the processor 1202. In this case, the processor 1202 may access the memory 1203 via an Input/Output (I/O) interface (not illustrated).

In the example in FIG. 8, the memory 1203 is used to store a group of software modules. The processor 1202 can execute the processing of the signal processing device 10 and the like, by reading and executing these software module groups from the memory 1203.

As described with reference to FIG. 8, each of the processors included in the signal processing device 10 and the like executes one or a plurality of programs including instructions for causing a computer to perform the algorithm described with reference to the drawings.

In the above-described example, the program includes instructions (or software codes) for causing the computer to perform one or more functions described in the example embodiments, in a case of being read by the computer. The program may be stored in a non-transitory computer-readable medium or a tangible storage medium. As an example and not by way of limitation, a computer-readable medium or tangible storage medium includes a random-access memory (RAM), a read-only memory (ROM), a flash memory, a solid-state drive (SSD), or other memory technologies, a CD-ROM, a digital versatile disc (DVD), a Blu-ray (registered trademark) disk, or other optical disk storages, a magnetic cassette, a magnetic tape, a magnetic disk storage, or other magnetic storage devices. The program may be transmitted through a transitory computer-readable medium or a communication medium. As an example and not by way of limitation, the transitory computer-readable medium or the communication medium includes propagated signals in electrical, optical, acoustic, or any other form.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with another example embodiment.

Each of the drawings is merely an example to illustrate one or more example embodiments. Each of the drawings is not associated with only one specific example embodiment, but may be associated with one or more other example embodiments. As those of ordinary skill in the art will appreciate, various features or steps described with reference to any one of the drawings may be combined with features or steps illustrated in one or more other drawings, for example, to create an example embodiment not explicitly illustrated or described. All of the features or steps illustrated in any one of the drawings for explaining exemplary example embodiments are not necessarily mandatory, and some features or steps may be omitted. The order of the steps described in any of the drawings may be changed as appropriate.

Some or all of the example embodiments described above may also be described as, but are not limited to, the following Supplementary Notes.

### (Supplementary Note 1)

A signal processing device including,
a compression unit for generating a first compressed signal by compressing an input signal having a predetermined length extracted from a received signal in a time domain,
a calculation unit for calculating cross-correlation between the first compressed signal and a second compressed signal generated by compressing a reference signal in a time domain,
a specification unit for specifying a synchronous position in the first compressed signal based on a calculation result of the cross-correlation, and
a conversion unit for converting the synchronous position in the first compressed signal into a synchronous position in the input signal.

### (Supplementary Note 2)

The signal processing device according to supplementary note 1, in which
the compression unit generates the first compressed signal by adding at least two adjacent samples in the input signal, and
the second compressed signal is generated by adding at least two adjacent samples of the reference signal.

### (Supplementary Note 3)

The signal processing device according to supplementary note 1, in which
the compression unit generates the first compressed signal by periodically extracting samples from the input signal in a case where the received signal is received via a path that causes a temporal spreading of the signal, and
the second compressed signal is generated by periodically extracting samples from the reference signal.

### (Supplementary Note 4)

The signal processing device according to any one of supplementary notes 1 to 3, in which
the compression unit converts the input signal into a non-integer oversampled signal, and
a processing unit for executing a demodulation processing on the input signal of which synchronous position is specified based on the non-integer oversampled signal by using information related to the non-integer oversampled signal is further provided.

### (Supplementary Note 5)

The signal processing device according to any one of supplementary notes 1 to 3, in which in a case where the input signal is compressed to have a length in a time domain of 1/M (M is an integer equal to or greater than two), the conversion unit multiplies a synchronous position in the first compressed signal by M.

### (Supplementary Note 6)

The signal processing device according to any one of supplementary notes 1 to 3, further including a reference signal compression unit for compressing the reference signal in a time domain to generate the second compressed signal.

### (Supplementary Note 7)

The signal processing device according to any one of supplementary notes 1 to 3, in which the compression unit extracts an input signal having a length of two frames from the received signal.

### (Supplementary Note 8)

The signal processing device according to supplementary note 2, in which the compression unit generates the first compressed signal by performing statistical processing on a value obtained by adding at least two adjacent samples in the input signal.

### (Supplementary Note 9)

A signal processing method including,
generating a first compressed signal by compressing an input signal having a predetermined length extracted from a received signal in a time domain,
calculating cross-correlation between the first compressed signal and a second compressed signal generated by compressing a reference signal in a time domain,
specifying a synchronous position in the first compressed signal based on a calculation result of the cross-correlation, and
converting the synchronous position in the first compressed signal into a synchronous position in the input signal.

### (Supplementary Note 10)

A program for causing a computer to execute,
generating a first compressed signal by compressing an input signal having a predetermined length extracted from a received signal in a time domain,
calculating cross-correlation between the first compressed signal and a second compressed signal generated by compressing a reference signal in a time domain,
specifying a synchronous position in the first compressed signal based on a calculation result of the cross-correlation, and
converting the synchronous position in the first compressed signal into a synchronous position in the input signal.

Some or all of the elements (e.g., configurations and functions) described in Supplementary Notes 2 to 8 dependent on Supplementary Note 1 may also depend on Supplementary Notes 9 and 10 by the depending relationships similar to those of Supplementary Notes 2 to 8. Some or all of the elements described in any supplementary note may be applied to various types of hardware, software, recording means for recording software, systems, and methods.

1. A signal processing device comprising:
at least one memory storing instructions; and
at least one processor configured to execute the instructions to,
generate a first compressed signal by compressing an input signal having a predetermined length extracted from a received signal in a time domain;
calculate cross-correlation between the first compressed signal and a second compressed signal generated by compressing a reference signal in a time domain;
specify a synchronous position in the first compressed signal based on a calculation result of the cross-correlation; and
convert the synchronous position in the first compressed signal into a synchronous position in the input signal.

2. The signal processing device according to claim 1, wherein the at least one processor is further configured to execute the instructions to generate the first compressed signal by adding at least two adjacent samples in the input signal, and
the second compressed signal is generated by adding at least two adjacent samples of the reference signal.

3. The signal processing device according to claim 1, wherein the at least one processor is further configured to execute the instructions to generate the first compressed signal by periodically extracting samples from the input signal in a case where the received signal is received via a path that causes a temporal spreading of the signal, and
the second compressed signal is generated by periodically extracting samples from the reference signal.

4. The signal processing device according to claim 1, wherein the at least one processor is further configured to execute the instructions to
convert the input signal into a non-integer oversampled signal, and
execute a demodulation processing on the input signal of which synchronous position is specified based on the non-integer oversampled signal by using information related to the non-integer oversampled signal is further provided.

5. The signal processing device according to claim 1, wherein in a case where the input signal is compressed to have a length in a time domain of 1/M (M is an integer equal to or greater than two), the at least one processor is further configured to execute the instructions to multiply a synchronous position in the first compressed signal by M.

6. The signal processing device according to claim 1, wherein the at least one processor is further configured to execute the instructions to compress the reference signal in a time domain to generate the second compressed signal.

7. The signal processing device according to claim 1, wherein the at least one processor is further configured to execute the instructions to extract an input signal having a length of two frames from the received signal.

8. The signal processing device according to claim 2, wherein the at least one processor is further configured to execute the instructions to generate the first compressed signal by performing statistical processing on a value obtained by adding at least two adjacent samples in the input signal.

9. A signal processing method comprising:
generating a first compressed signal by compressing an input signal having a predetermined length extracted from a received signal in a time domain;
calculating cross-correlation between the first compressed signal and a second compressed signal generated by compressing a reference signal in a time domain;
specifying a synchronous position in the first compressed signal based on a calculation result of the cross-correlation; and
converting the synchronous position in the first compressed signal into a synchronous position in the input signal.

10. A non-transitory computer-readable medium storing a program for causing a computer to execute,
generating a first compressed signal by compressing an input signal having a predetermined length extracted from a received signal in a time domain;
calculating cross-correlation between the first compressed signal and a second compressed signal generated by compressing a reference signal in a time domain;
specifying a synchronous position in the first compressed signal based on a calculation result of the cross-correlation; and
converting the synchronous position in the first compressed signal into a synchronous position in the input signal.
